(19) United States
(12) Patent Application Publication
(10) Pub. No.: US 2025/0201702 A1
(43) Pub. Date: Jun. 19, 2025

(54) INTEGRATED CIRCUIT AND PACKAGE INCLUDING INDUCTOR AND VERTICAL INTERCONNECTS

(71) Applicant: Samsung Electronics Co., Ltd., Suwon-si (KR)

(72) Inventors: Sangwook HAN, Suwon-si (KR); Kyoungmin LEE, Suwon-si (KR); Kyungsoo LEE, Suwon-si (KR); Junho HUH, Suwon-si (KR)

(73) Assignee: Samsung Electronics Co., Ltd., Suwon-si (KR)

(21) Appl. No.: 18/954,729

(22) Filed: Nov. 21, 2024

(30) Foreign Application Priority Data
Dec. 18, 2023 (KR) 10-2023-0185158
Mar. 4, 2024 (KR) 10-2024-0030910

(51) Int. Cl. H01L 23/522; H01L 23/00; H01L 23/528; H01L 23/535; H01L 25/065

(52) U.S. Cl. CPC H01L 23/5227; H01L 23/5226; H01L 23/5283; H01L 23/535; H01L 24/16; H01L 25/0657; H01L 2224/16146; H01L 2924/1206

(57) ABSTRACT

Provided is an integrated circuit including a first die including a first substrate and a plurality of through silicon vias (TSVs) penetrating through the first substrate, and a second die disposed below the first die in a vertical direction perpendicular to an in-plane direction of the first die and including a second substrate and a plurality of conductive interconnects electrically connected to separate, respective TSVs of the plurality of TSVs, wherein the first die further includes an inductor in at least one first layer over the first substrate in the vertical direction, and the inductor at least partially overlaps at least one TSV of the plurality of TSVs in the vertical direction.

### CROSS-REFERENCE TO RELATED APPLICATIONS

This application is based on and claims priority under 35 U.S.C. § 119 to Korean Patent Application No. 10-2023-0185158, filed on Dec. 18, 2023 in the Korean Intellectual Property Office, and Korean Patent Application No. 10-2024-0030910, filed on Mar. 4, 2024 in the Korean Intellectual Property Office, the disclosures of each of which are incorporated by reference herein in their entirety.

### BACKGROUND

The inventive concepts relate to integrated circuits and packages, and more particularly, to integrated circuits and packages including inductors and vertical interconnects.

An integrated circuit manufactured through a semiconductor process may include circuits that process signals. For example, an integrated circuit may include a circuit that processes analog signals, a circuit that processes digital signals, and/or a circuit that processes mixed signals including analog signals and digital signals. A circuit that processes analog signals may include not only active devices such as transistors, but also passive devices such as capacitors and inductors. An active device formed through a semiconductor process may have a relatively small area, while a passive device formed through a semiconductor process may have a relatively large area. Therefore, it may be important to efficiently implement passive devices in an integrated circuit.

### SUMMARY

Some example embodiments of the inventive concepts provide an integrated circuit and a package including inductors efficiently disposed based on a structure for interconnecting stacked dies.

According to some example embodiments of the inventive concepts, an integrated circuit may include a first die, the first die including a first substrate and a plurality of through silicon vias (TSVs), the plurality of TSVs penetrating through the first substrate; and a second die below the first die in a vertical direction, the second die including a second substrate and a plurality of conductive interconnects, the plurality of conductive interconnects electrically connected to separate, respective TSVs of the plurality of TSVs, the vertical direction extending perpendicular to an in-plane direction of the first die. The first die may further include an inductor in at least one first layer over the first substrate in the vertical direction. The inductor may at least partially overlap at least one TSV of the plurality of TSVs in the vertical direction.

According to some example embodiments of the inventive concepts, an integrated circuit may include a first die, the first die including a first substrate and a plurality of first conductive interconnects, the plurality of first conductive interconnects below the first substrate; and a second die below the first die in a vertical direction, the second die including a plurality of second conductive interconnects, the plurality of second conductive interconnects electrically connected to separate, respective first conductive interconnects of the plurality of first conductive interconnects, the vertical direction extending perpendicular to an in-plane direction of the first die. The first die may further include an inductor in at least one first layer below the first substrate in the vertical direction. The plurality of first conductive interconnects may include at least one first conductive interconnect, the at least one first conductive interconnect including a pattern at least partially inside the inductor in the at least one first layer.

According to some example embodiments of the inventive concepts, an integrated circuit may include a first die, the first die including an inductor in at least one first layer, and a first circuit configured to process an analog signal. The integrated circuit may include a second die below the first die, the second die including a second circuit, the second circuit configured to perform at least one of transmitting a plurality of signals to the first circuit, or receiving a plurality of signals from the first circuit. The first die may further include a plurality of first conductive interconnects, the integrated circuit configured to apply the plurality of signals to the plurality of first conductive interconnects. At least one first conductive interconnect of the plurality of first conductive interconnects may overlap an inner region of the inductor in a vertical direction, the vertical direction extending perpendicular to an in-plane direction of the first die.

### BRIEF DESCRIPTION OF THE DRAWINGS

Embodiments of the inventive concepts will be more clearly understood from the following detailed description taken in conjunction with the accompanying drawings in which:

FIG. 1 is a circuit diagram showing a circuit according to some example embodiments;

FIGS. 2A and 2B are diagrams showing examples of an inductor according to some example embodiments;

FIGS. 3A and 3B are cross-sectional views of examples of integrated circuits according to some example embodiments;

FIGS. 4A and 4B are cross-sectional views of examples of integrated circuits according to some example embodiments;

FIGS. 5A and 5B are plan views of examples of integrated circuits according to some example embodiments;

FIGS. 6A and 6B are cross-sectional views of examples of integrated circuits according to some example embodiments;

FIGS. 7A and 7B are cross-sectional views of examples of integrated circuits according to some example embodiments;

FIG. 8 is a plan view of an integrated circuit according to some example embodiments;

FIG. 9 is a block diagram showing a communication device according to some example embodiments;

FIGS. 10A and 10B are flowcharts of examples of methods of designing an integrated circuit according to some example embodiments; and

FIG. 11 is a block diagram showing a computing system including a memory storing a program according to some example embodiments.

### DETAILED DESCRIPTION

Below, with reference to the attached drawings, some example embodiments of the present inventive concepts will be described in detail so that those skilled in the art can easily implement the present inventive concepts. However, the present inventive concepts may be implemented in many different forms and are not limited to the example embodiments described herein.

In order to clearly explain the present inventive concepts in the drawings, parts that are not related to the description are omitted, and similar parts are given similar reference numerals throughout the specification. In the flowchart described with reference to the drawings, the order of operations may be changed, several operations may be merged, certain operations may be divided, and certain operations may not be performed.

Additionally, expressions written in the singular may be interpreted as singular or plural, unless explicit expressions such as “one” or “single” are used. Terms containing ordinal numbers, such as first, second, etc., may be used to describe various elements, but the elements are not limited by these terms. These terms may be used for the purpose of distinguishing one component from another.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below or horizontally adjacent to the reference element, and it is not necessarily referred to as being positioned “above” or “on” in a direction opposite to gravity.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these numerical values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

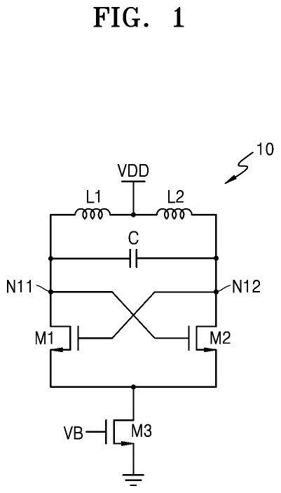

FIG. 1 is a circuit diagram showing a circuit 10 according to some example embodiments. For example, the circuit diagram of FIG. 1 shows a differential LC oscillator as a circuit 10 that processes analog signals in an integrated circuit manufactured through a semiconductor process. As shown in FIG. 1, the circuit 10 may include a first transistor M1, a second transistor M2, a third transistor M3, a capacitor C, a first inductor L1, and a second inductor L2. The circuit 10 of FIG. 1 is merely an example of a circuit included in an integrated circuit, and example embodiments of the inventive concepts are not limited to the circuit 10 of FIG. 1.

The first transistor M1, the second transistor M2, and the third transistor M3 may be n-channel field-effect transistors (NFETs). As shown in FIG. 1, the first transistor M1 and the second transistor M2 may be commonly connected to the third transistor M3 (e.g., coupled in parallel thereto) and may be cross-coupled (e.g., respective gates thereof may be cross-coupled) at a first node N11 and a second node N12. The third transistor M3 may have a gate to which a bias voltage VB is applied and may function as a current source.

The first transistor M1, the second transistor M2, and the third transistor M3 may be active devices and may be formed through a semiconductor process. For example, the first transistor M1, the second transistor M2, and the third transistor M3 may each be one of a FinFET including at least one fin and a gate electrode, a gate-all-around FET (GAAFET) including at least one nanowire and a gate electrode, a multi-bridge channel FET (MBCFET) including at least one nanosheet and a gate electrode, or a vertical FET (VFET) in which the outer periphery of an active pattern may be formed by a gate electrode. Also, the first transistor M1, the second transistor M2, and the third transistor M3 may each be one of a ForkFET in which, as nanosheets for a P-type transistor and nanosheets for an N-type transistor are separated by a dielectric wall, the N-type transistor and the P-type transistor have structures closer to each other, a complementary FET (CFET), a negative capacitance FET (NCFET), or a carbon nanotube (CNT) FET. Also, the first transistor M1, the second transistor M2, and the third transistor M3 may each be a bipolar junction transistor in addition to the FETs described above.

The capacitor C may be connected between the first node N11 and the second node N12. The first inductor L1 and the second inductor L2 may be connected to each other in series between the first node N11 and the second node N12. A positive supply voltage VDD may be applied to a node to which the first inductor L1 and the second inductor L2 are connected. An oscillating signal having a frequency based on the capacitance of the capacitor C and the inductances of the first inductor L1 and the second inductor L2 may be generated at the first node N11 and the second node N12. According to some example embodiments, an LC oscillator may be used to generate an input of a mixer in a transceiver used in wireless communications.

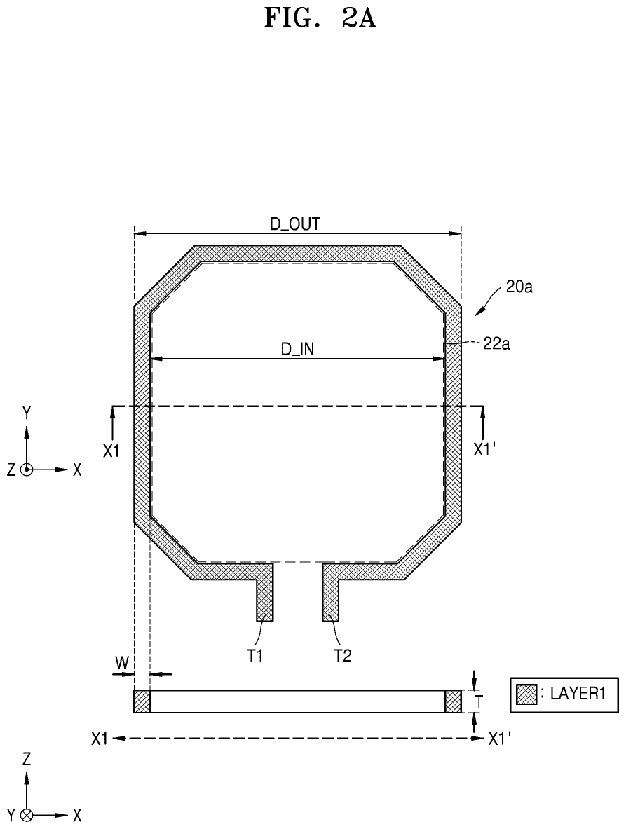

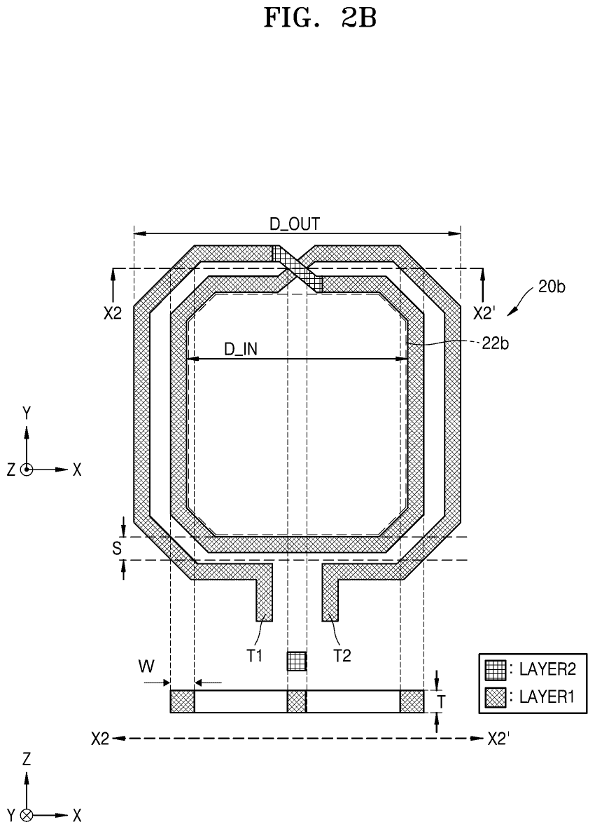

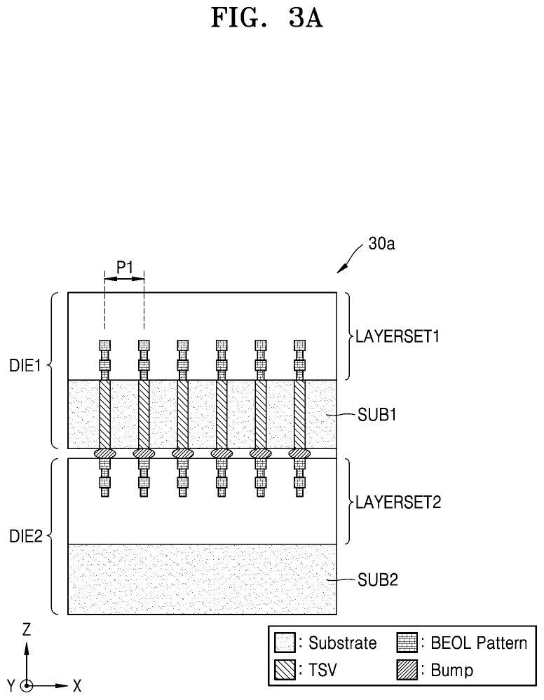

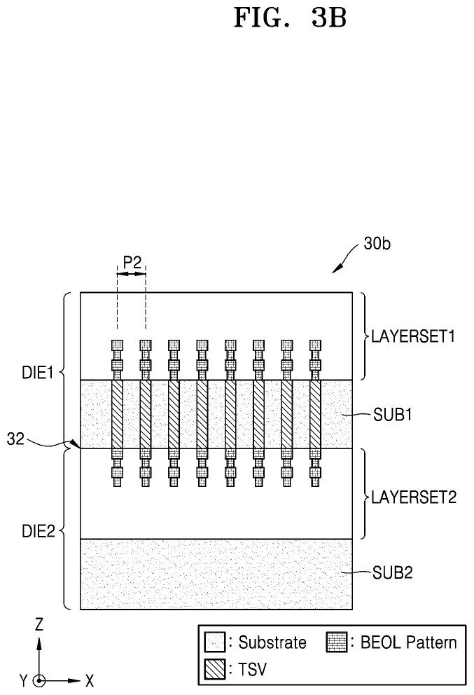

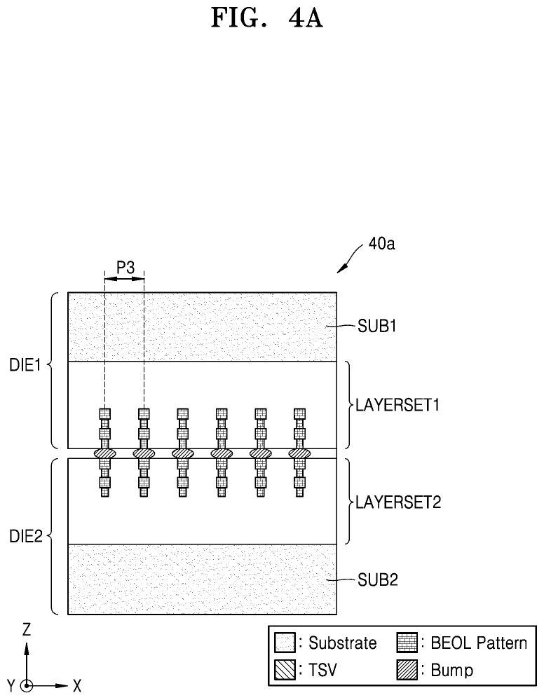

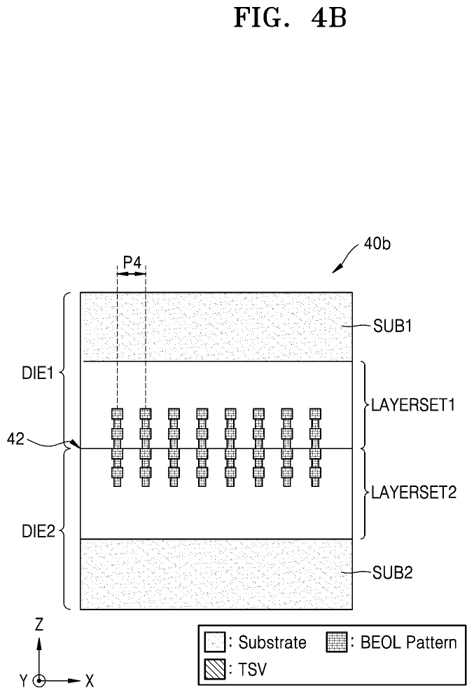

Passive devices may be formed through a semiconductor process, and the passive devices may have a larger area (e.g., larger size, occupy a larger area in a plan view of an integrated circuit including same) than active devices. For example, the first inductor L1 and/or the second inductor L2 may each be implemented as a spiral inductor, as will be described later with reference to FIGS. 2A and 2B, and the spiral inductor may have a larger area (e.g., occupy a larger area in a plan view of an integrated circuit including same) than an active device. Therefore, the area of the circuit 10 may depend on the areas of the first inductor L1 and the second inductor L2. To connect two dies, as described below with reference to FIGS. 3A and 3B and FIGS. 4A and 4B, dies may include a plurality of vertical interconnects. An inductor may at least partially overlap at least one vertical interconnect of the plurality of vertical interconnects in a vertical direction (e.g., a direction extending perpendicular to an in-plane direction of one or both of the two dies), and thus the area of an integrated circuit (e.g., an area of the integrated circuit in a plan view directed perpendicular to the in-plane direction) may be reduced. Also, space constraints on an inductor may be reduced, thereby facilitating implementation of an inductor with desired specifications (e.g., a larger inductor) and improving the performance of an integrated circuit without compromising space constraints of the integrated circuit and thus improving functionality of the integrated circuit and/or a device that includes the integrated circuit. Additionally, integration of the integrated circuit may be improved, and thus miniaturization of the integrated circuit may be improved without compromising performance of the integrated circuit, based on the space constraints on the inductor being reduced based on the inductor at least partially overlapping at least one vertical interconnect of the plurality of vertical interconnects in a vertical direction (e.g., a direction extending perpendicular to an in-plane direction of one or both of the two dies), such that the area of an integrated circuit (e.g., an area of the integrated circuit in a plan view directed perpendicular to the in-plane direction) may be reduced.

FIGS. 2A and 2B are diagrams showing examples of an inductor according to some example embodiments. For example, the upper part of FIG. 2A shows an inductor 20a having the number of turns of 1 on the plane including the X axis and the Y axis, and the lower part of FIG. 2A shows a cross-section of the inductor 20a taken along a line X1-X1′. Also, the upper part of FIG. 2B shows an inductor 20b having the number of turns of 2 on the plane including the X axis and the Y axis, and the lower part of FIG. 2B shows a cross-section of the inductor 20b taken along a line X2-X2′. As described above with reference to FIG. 1, an integrated circuit may include an inductor, and the inductor included in the integrated circuit is not limited to inductors 20a and 20b of FIGS. 2A and 2B. Hereinafter, descriptions of FIGS. 2A and 2B identical to each other are omitted.

Herein, the X-axis direction and the Y-axis direction may be referred to as a first horizontal direction and a second horizontal direction, respectively, and the Z-axis direction may be referred to as a vertical direction. A plane including an X-axis and a Y-axis may be referred to as a horizontal plane, components placed in the +Z direction relative to other components may be referred to as being above the other components, and components placed in the −Z direction relative to other components may be referred to as being below the other components. Also, an area of a component may refer to a size occupied by the component in a plane parallel to the horizontal plane, and a width of a component may refer to a length of the component in a direction perpendicular to the direction in which the component extends. A surface exposed in the +Z direction may be referred to as a top surface, a surface exposed in the −Z direction may be referred to as a bottom surface, and a surface exposed in the +X direction or the +Y direction may be referred to as a side surface. In the drawings, only some of layers may be shown for convenience of illustration.

Referring to FIG. 2A, the inductor 20a may include a pattern formed in a first layer LAYER1 having a thickness T (e.g., a thickness in the vertical direction). An integrated circuit may include conductive patterns formed in a plurality of layers stacked in the vertical direction. For example, an integrated circuit may include wires formed in wiring layers and may include vias formed in via layers between the wiring layers. Herein, a conductive pattern may simply be referred to as a pattern. The inductor 20a may have an inductance defined based on a width W (e.g., a width in the X-axis and/or Y-axis directions), an inner diameter D_IN, and an outer diameter D_OUT. The inductor 20a may include a first terminal T1 and a second terminal T2, and the first terminal T1 and the second terminal T2 may be spaced apart from each other in the X-axis direction. Herein, a region having a length in the X-axis direction corresponding to the inner diameter D_IN and surrounded by a pattern may be referred to as an inner region 22a of the inductor 20a, and the area of the inner region 22a may be referred to as an inner area. Hereinafter, descriptions will be given mainly with reference to the inductor 20a of FIG. 2A, but embodiments of the inventive concepts are not limited to the inductor 20a.

Referring to FIG. 2B, the inductor 20b may have a first terminal T1 and a second terminal T2 and may include patterns formed in a first layer LAYER1 and a second layer LAYER2. For example, the second layer LAYER2 may be an upper layer of the first layer LAYER1, and the pattern of the second layer LAYER2 may be provided in a region where the patterns of the first layer LAYER1 need to intersect with each other. Although not shown in FIG. 2B, the inductor 20b may include vias connected to the patterns of the first layer LAYER1 and the patterns of the second layer LAYER2. The inductor 20b may have an inductance defined based on the width W, the inner diameter D_IN, the outer diameter D_OUT, and a space S. The inductor 20b may include the first terminal T1 and the second terminal T2, and the first terminal T1 and the second terminal T2 may be spaced apart from each other in the X-axis direction. Herein, a region having a length in the X-axis direction corresponding to the inner diameter D_IN and surrounded by a pattern may be referred to as an inner region 22b of the inductor 20b, and the area of the inner region 22b may be referred to as an inner area.

FIGS. 3A and 3B are cross-sectional views of examples of integrated circuits according to some example embodiments. For example, the cross-sectional views of FIGS. 3A and 3B show integrated circuits 30a and 30b including two dies stacked in the vertical direction, that is, a first die DIE1 and a second die DIE2. Hereinafter, descriptions of elements of FIGS. 3A and 3B identical to each other are omitted.

According to some example embodiments, an integrated circuit may include two dies stacked in the vertical direction. It will be understood that the “vertical direction” as described herein (e.g., Z-axis direction) may be perpendicular to an in-plane direction of the first substrate SUB1 and/or the second substrate SUB2, so as to be perpendicular to an upper surface and/or a bottom surface thereof. It will be understood that the “vertical direction” as described herein (e.g., Z-axis direction) may be perpendicular to an in-plane direction of the first die DIE1 and/or the second die DIE2, so as to be perpendicular to an upper surface and/or a bottom surface thereof. The X-axis and Y-axis directions may be understood to be perpendicular to the Z-axis direction and perpendicular to each other. Each of the X-axis and Y-axis directions may be parallel to an in-plane direction of the first substrate SUB1 and/or the second substrate SUB2, so as to be parallel to an upper surface and/or a bottom surface thereof. Each of the X-axis and Y-axis directions may be parallel to an in-plane direction of the first die DIE1 and/or the second die DIE2, so as to be parallel to an upper surface and/or a bottom surface thereof. The X-axis and Y-axis directions may be referred to as a different one of a first horizontal direction or a second horizontal direction. A die may be separated from a wafer manufactured through a semiconductor process and may also be referred to as a chip. An integrated circuit may include dies respectively separated from different wafers, and the dies may be stacked and interconnected in the vertical direction. For example, when two or more circuits that need (e.g., are manufactured according to) different sub-processes of a semiconductor process, such as an analog circuit and a logic circuit, are integrated into one die, the die may have a large area (e.g., a large size in one or more horizontal directions parallel to the in-plane direction(s) of the first and/or second substrate SUB1 and/or SUB2, a large size in one or more horizontal directions parallel to the in-plane direction(s) of the first and/or second die DIE1 and/or DIE2, etc.), and the cost of the semiconductor process (e.g., the process to manufacture the integrate circuit) may increase, and the yield of the die may decrease. Therefore, when a die in which an analog circuit is integrated and a die in which a digital circuit is integrated are manufactured independently of each other and then the two dies are interconnected, an integrated circuit including the dies may exhibit reduced area, reduced cost of the semiconductor process, and high yield, and thus the manufacturing cost of the integrated circuit and any device including same may be reduced. As described above, vertically stacked dies may be included in one package, and such a package may be referred to as a multi-chip package (MCP). Also, each of dies included in one package may be referred to as a chiplet.

Vertical interconnects may be formed in each of the vertically stacked dies, where the vertical interconnects may be configured to enable signals to be transmitted and received between the vertically stacked dies. The vertical interconnects in the respective dies may at least partially comprise separate, respective circuits. Herein, an interconnect may refer to a unit in which patterns including a conductive material are electrically connected to each other to provide a signal path. For example, an interconnect may include a wire formed in a wiring layer, a via formed in a via layer, and/or a through silicon via (TSV) penetrating through a substrate. Herein, a vertical interconnect may refer to an interconnect that extends in the vertical direction to be electrically connected to another die.

Referring to FIG. 3A, an integrated circuit 30a may include the first die DIE1 and the second die DIE2, and the first die DIE1 may be stacked on the second die DIE2 (e.g., on the second die DIE2 in the Z-axis direction). Restated, the second die DIE2 may be below the first die DIE1 in the Z-axis direction (e.g., vertical direction). The first die DIE1 may include a first substrate SUB1, and the second die DIE2 may include a second substrate SUB2. According to some example embodiments, a substrate may have the p-type of conductivity, and active devices, such as transistors, may be formed on the substrate. A front-end-of-line (FEOL) may include, for example, planarizing and cleaning the wafer, forming a trench, forming a well, forming a gate electrode, and forming a source and a drain. Transistors may be formed on a substrate though FEOL. For example, a back-end-of-line (BEOL) may include operations like silicidation of a gate, a source region, and a drain region, adding a dielectric, planarizing, forming holes, adding metal layers, forming vias, and forming a passivation layer. Interconnects may be formed through BEOL. In some example embodiments, a middle-of-line (MOL) may be performed between the FEOL and the BEOL, and contacts may be formed on individual devices. Next, the integrated circuit 30a may be packaged in a semiconductor package and used as a component for various applications.

As shown in FIG. 3A, the first and second dies DIE1 and DIE2 may include respective first and second sets of one or more layers LAYERSET1 and LAYERSET2 which may include portions of the respective dies DIE1 and DIE2 that exclude the respective first and second substrates SUB1 and SUB2 thereof. The first die DIE1 may be understood to include the first substrate SUB1 and the first set of one or more layers LAYERSET1. The second die DIE2 may be understood to include the second substrate SUB2 and the second set of one or more layers LAYERSET2. As shown, the BEOL pattern in the first die DIE1 may be located in, at least partially surrounded by, and/or at least partially penetrate one or more layers of the first set of one or more layers LAYERSET1. As shown, the BEOL pattern in the second die DIE2 may be located in, at least partially surrounded by, and/or at least partially penetrate one or more layers of the second set of one or more layers LAYERSET2. The respective first and second sets of one or more layers LAYERSET1 and LAYERSET2 may include one or more layers including one or more patterns of insulating material (e.g., silicon oxide material), conductive material (e.g., metal such as copper, doped polysilicon, etc.), wiring patterns, circuitry patterns, or the like.

As shown in FIG. 3A, when the first substrate SUB1 of the first die DIE1 is adjacent to the second die DIE2, the first die DIE1 may include TSVs penetrating through the first substrate SUB1 in the vertical direction, that is, the Z-axis direction. As shown in FIG. 3A, BEOL patterns may be disposed over the first substrate SUB1, and TSVs respectively connected to the BEOL patterns (e.g., TSVs connected to separate, respective BEOL patterns) may penetrate through the first substrate SUB1 in the Z-axis direction. The second die DIE2 may include BEOL patterns (e.g., conductive interconnects) that are electrically connected to TSVs, respectively (e.g., the conductive interconnects may be electrically connected to separate, respective TSVs of the plurality of TSVs of the first die DIE1). Therefore, the first die DIE1 may include a vertical interconnect including a BEOL pattern and a TSV, and the second die DIE2 may include a vertical interconnect including a BEOL pattern.

The integrated circuit 30a may include a plurality of bumps between the first die DIE1 and the second die DIE2. For example, as shown in FIG. 3A, the bumps may be disposed between TSVs of the first die DIE1 and BEOL patterns of the second die DIE2, such that the bumps may be understood to be electrically connected to separate, respective TSVs of the first die DIE1. Therefore, the TSVs of the first die DIE1 and the BEOL patterns of the second die DIE2 may be electrically connected to each other through the bumps. According to some example embodiments, a pitch needed between the bumps (e.g., dozens of μm) may be greater than a pitch needed between the TSVs (e.g., several μm), and thus a pitch P1 of vertical interconnects of the first die DIE1 and the second die DIE2 may correspond to the pitch of the bumps. According to some example embodiments, the bumps may be disposed at a pitch of dozens of μm and may be referred to as micro-bumps.

Referring to FIG. 3B, an integrated circuit 30b may include the first die DIE1 and the second die DIE2, and the first die DIE1 may be stacked on the second die DIE2 e.g., on the second die DIE2 in the Z-axis direction). The first die DIE1 may include a first substrate SUB1, and the second die DIE2 may include a second substrate SUB2. As shown in FIG. 3B, the first substrate SUB1 of the first die DIE1 may be adjacent to the second die DIE2, the first die DIE1 may include TSVs penetrating through the first substrate SUB1 in the Z-axis direction. BEOL patterns may be disposed over the first substrate SUB1, and TSVs respectively connected to the BEOL patterns may penetrate through the first substrate SUB1 in the Z-axis direction. The second die DIE2 may include BEOL patterns (e.g., conductive interconnects) that are electrically connected to TSVs, respectively (e.g., the second die DIE2 may include conductive interconnects electrically connected to separate, respective TSVs of the first die DIE1). Therefore, the first die DIE1 may include a vertical interconnect including a BEOL pattern and a TSV, and the second die DIE2 may include a vertical interconnect including a BEOL pattern. As shown in FIG. 3B, the first and second dies DIE1 and DIE2 may include respective first and second sets of one or more layers LAYERSET1 and LAYERSET2 which may include portions of the respective dies DIE1 and DIE2 that exclude the respective first and second substrates SUB1 and SUB2 thereof. In some example embodiments, the BEOL pattern of the first die DIE1 may at least partially comprise a first circuit configured to process an analog signal, and the BEOL pattern of the second die DIE2 may at least partially comprise a second circuit configured to transmit a plurality of signals to the first circuit and/or receive a plurality of signals from the first circuit.

In the integrated circuit 30b, the first die DIE1 and the second die DIE2 may be interconnected (e.g., directly interconnected) through hybrid bonding. Hybrid bonding may include interfacial bonding between oxide surfaces and interfacial bonding between metal surfaces, and the interfacial bonding may refer to bonding of two surfaces, which contact each other, by intermolecular forces. In particular, when interfacial bonding occurs between Cu surfaces, hybrid bonding may be referred to as hybrid copper bonding (HCB) or copper hybrid bonding (CHB). Due to the hybrid bonding, as shown in FIG. 3B, the TSVs of the first die DIE1 and the BEOL patterns of the second die DIE2 may be bonded to each other (e.g., bonded directly to each other) at the interface 32 between the first die DIE1 and the second die DIE2. Compared to the integrated circuit 30a of FIG. 3A, bumps may be omitted in the integrated circuit 30b of FIG. 3B. Therefore, a pitch P2 of vertical interconnects of the first die DIE1 and the second die DIE2 may correspond to a pitch (e.g., several μm) needed between TSVs.

FIGS. 4A and 4B are cross-sectional views of examples of integrated circuits according to some example embodiments. For example, the cross-sectional views of FIGS. 4A and 4B show integrated circuits 40a and 40b including two dies stacked in the vertical direction, that is, a first die DIE1 and a second die DIE2. Hereinafter, descriptions of FIGS. 4A and 4B identical to those given above with reference to drawings (e.g., FIGS. 3A and 3B) will be omitted.

Referring to FIG. 4A, an integrated circuit 40a may include the first die DIE1 and the second die DIE2, and the first die DIE1 may be stacked on the second die DIE2 (e.g., in the Z-axis direction). Restated, the second die DIE2 may be below the first die DIE1 in the (Z-axis direction (e.g., vertical direction). The first die DIE1 may include the first substrate SUB1, and the second die DIE2 may include the second substrate SUB2. Unlike some example embodiments, including the example embodiments of FIGS. 3A and 3B in which the first substrate SUB1 of the first die DIE1 is adjacent to the second die DIE2, the first substrate SUB1 of the first die DIE1 may be spaced apart from the second die DIE2. Therefore, as shown in FIG. 4A, BEOL patterns (e.g., first conductive interconnects) of the first die DIE1 may be disposed under the first substrate SUB1 (e.g., in the −Z direction). The second die DIE2 may include BEOL patterns (e.g., second conductive interconnects) that are electrically connected to BEOL patterns of the first die DIE1, respectively (e.g., the second conductive interconnects of the second die DIE2 may be electrically connected to separate, respective first conductive interconnects of the first die DIE1). Therefore, the first die DIE1 may include a vertical interconnect including a BEOL pattern, and the second die DIE2 may include a vertical interconnect including a BEOL pattern. As shown in FIG. 4A, the first and second dies DIE1 and DIE2 may include respective first and second sets of one or more layers LAYERSET1 and LAYERSET2 which may include portions of the respective dies DIE1 and DIE2 that exclude the respective first and second substrates SUB1 and SUB2 thereof. In some example embodiments, the BEOL pattern of the first die DIE1 may at least partially comprise a first circuit configured to process an analog signal, and the BEOL pattern of the second die DIE2 may at least partially comprise a second circuit configured to transmit a plurality of signals to the first circuit and/or receive a plurality of signals from the first circuit.

The integrated circuit 40a may include a plurality of bumps between the first die DIE1 and the second die DIE2. For example, as shown in FIG. 4A, the bumps may be disposed between the BEOL patterns of the first die DIE1 and BEOL patterns of the second die DIE2. The bumps may be electrically connected to separate, respective BEOL patterns of the first and second dies DIE1 and DIE2 (e.g., separate, respective first and second conductive interconnects). Therefore, the BEOL patterns of the first die DIE1 and the BEOL patterns of the second die DIE2 may be electrically connected to each other through the bumps. Therefore, a pitch P3 of vertical interconnects of the first die DIE1 and the second die DIE2 may correspond to the pitch of the bumps.

Referring to FIG. 4B, an integrated circuit 40b may include the first die DIE1 and the second die DIE2, and the first die DIE1 may be stacked on the second die DIE2 (e.g., in the Z-axis direction). The first die DIE1 may include the first substrate SUB1, and the second die DIE2 may include the second substrate SUB2. As shown in FIG. 4B, the first substrate SUB1 of the first die DIE1 may be spaced apart from the second die DIE2, and BEOL patterns of the first die DIE1 may be disposed under the first substrate SUB1. The second die DIE2 may include BEOL patterns that are electrically connected to BEOL patterns of the first die DIE1, respectively. Therefore, the first die DIE1 may include a vertical interconnect including a BEOL pattern, and the second die DIE2 may include a vertical interconnect including a BEOL pattern. As shown in FIG. 4B, the first and second dies DIE1 and DIE2 may include respective first and second sets of one or more layers LAYERSET1 and LAYERSET2 which may include portions of the respective dies DIE1 and DIE2 that exclude the respective first and second substrates SUB1 and SUB2 thereof. In some example embodiments, the BEOL pattern of the first die DIE1 may at least partially comprise a first circuit configured to process an analog signal, and the BEOL pattern of the second die DIE2 may at least partially comprise a second circuit configured to transmit a plurality of signals to the first circuit and/or receive a plurality of signals from the first circuit.

In the integrated circuit 40b, the first die DIE1 and the second die DIE2 may be interconnected (e.g., directly interconnected) through hybrid bonding. As described above with reference to FIG. 3B, the hybrid bonding may include interfacial bonding between oxide surfaces and interfacial bonding between metal surfaces and may be HCB when a metal constituting the metal surfaces is Cu. Due to the hybrid bonding, as shown in FIG. 4B, the BEOL patterns of the first die DIE1 and the BEOL patterns of the second die DIE2 may be bonded to each other (e.g., bonded directly to each other) at the interface 42 between the first die DIE1 and the second die DIE2. Compared to the integrated circuit 40a of FIG. 4A, bumps may be omitted in the integrated circuit 40b of FIG. 4B. Therefore, a pitch P4 of vertical interconnects of the first die DIE1 and the second die DIE2 may correspond to a pitch needed between BEOL patterns.

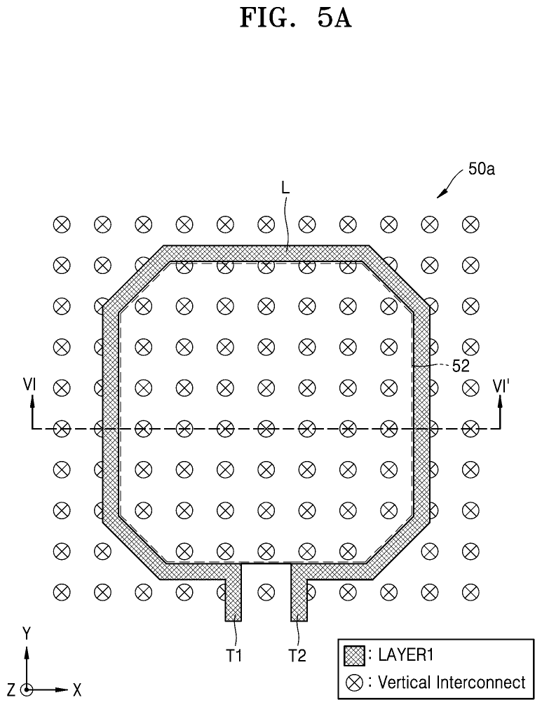

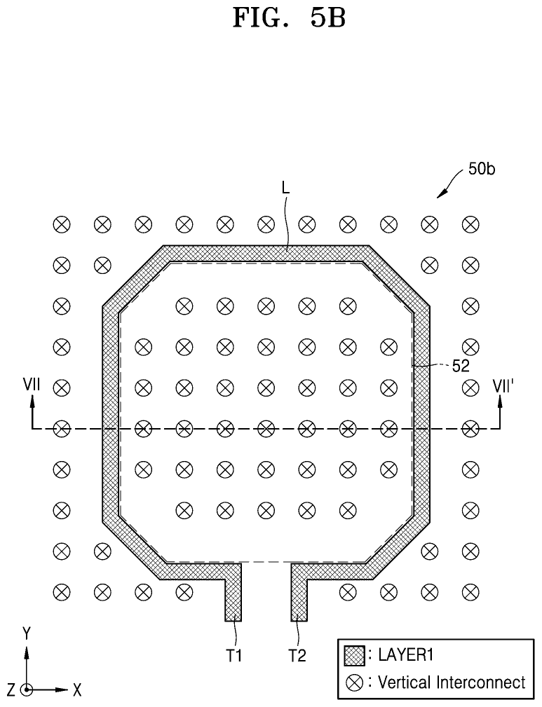

FIGS. 5A and 5B are plan views of examples of integrated circuits according to some example embodiments. For example, FIGS. 5A and 5B are plan views of integrated circuits 50a and 50b each including an inductor L and vertical interconnects. Hereinafter, descriptions of FIGS. 5A and 5B identical to each other are omitted.

According to some example embodiments, the inductor L may vertically overlap (e.g., in the Z-axis direction) at least one vertical interconnect of a plurality of vertical interconnects for interconnecting two dies. Herein, overlapping of the inductor L and a vertical interconnect in the vertical direction may include overlapping of the inner region 52 of the inductor L and the vertical interconnect in the vertical direction. As described above with reference to FIGS. 3A and 3B and 4A and 4B, an integrated circuit may include two dies stacked (e.g., stacked in the Z-axis direction), and the two dies may each include vertical interconnects. When the inductor L and the vertical interconnects are disposed (e.g., disposed in a die) as shown in FIGS. 5A and 5B, an eddy current induced by the inductor L may occur on the plane including the X axis and the Y axis. and thus the eddy current may not affect signals transmitted through one or more of the vertical interconnects. Also, the loop of an eddy current induced by a vertical interconnect that is smaller than the inductor L may be small, and thus the influence of the vertical interconnect on the inductor L or the quality factor (Q-factor) of the inductor L may be insignificant.

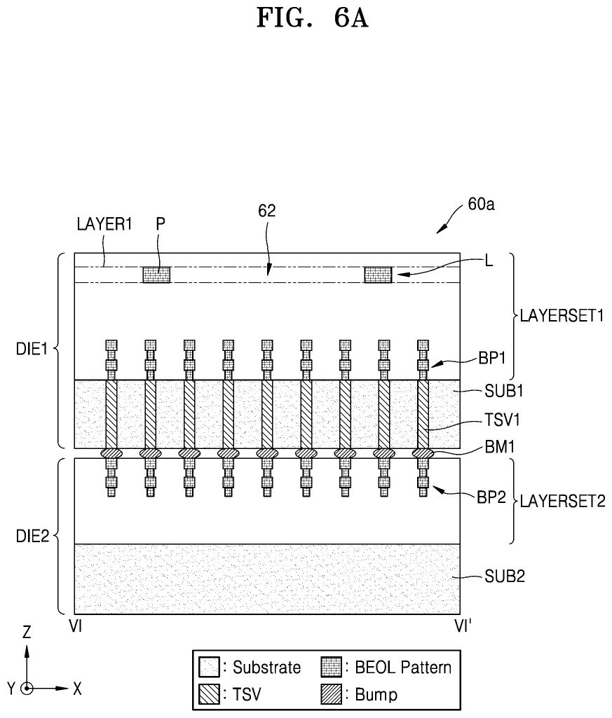

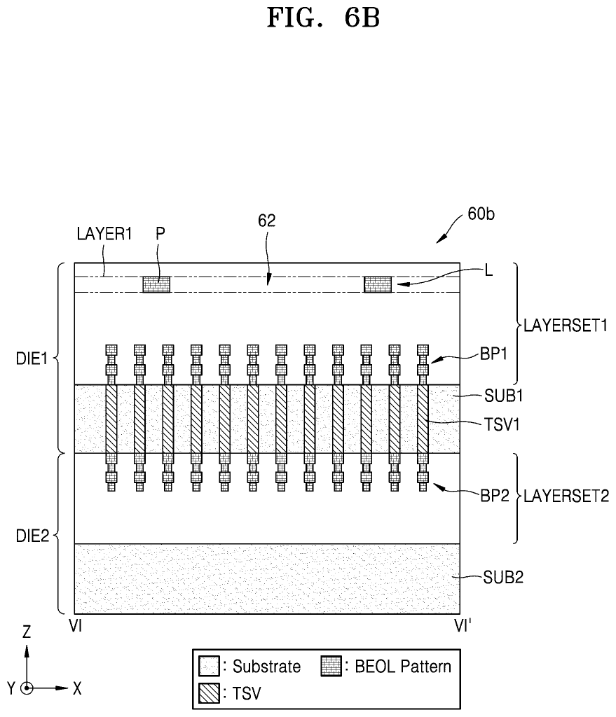

Referring to FIG. 5A, the inductor L may be disposed over the vertical interconnects. For example, the inductor L may at least partially overlap the vertical interconnects in a vertical direction (e.g., the Z-axis direction). The inductor L may include a pattern formed in a first layer LAYER1 and may include the first terminal T1 and the second terminal T2. As will be described later with reference to FIGS. 6A and 6B, the first layer LAYER1 in which the pattern of the inductor L is formed may be thicker than each of layers of the vertical interconnects. The vertical interconnects disposed below the inductor L (e.g., below in the Z-axis direction) may include vertical interconnects at least partially overlapping the pattern of the inductor L in the Z-axis direction and vertical interconnects at least partially overlapping the inner region 52 of the inductor L in the Z-axis direction. Therefore, a region in which the inductor L is disposed and a region in which the vertical interconnects are disposed may at least partially overlap each other (e.g., in the Z-axis direction), and an integrated circuit 50a may have a reduced area (e.g., a reduced area in the XY plane). Examples of cross-sections of the integrated circuit 50a of FIG. 5A cut along a plane including the X-axis and the Z-axis will be described later with reference to FIGS. 6A and 6B.

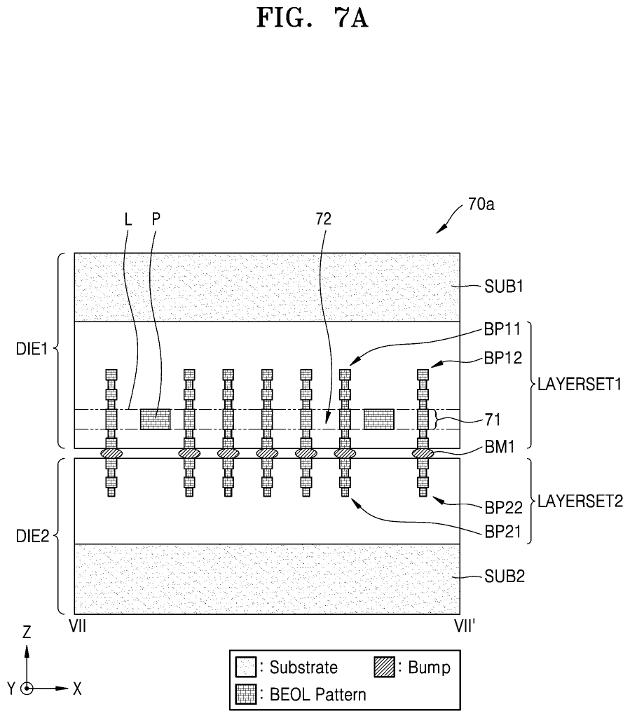

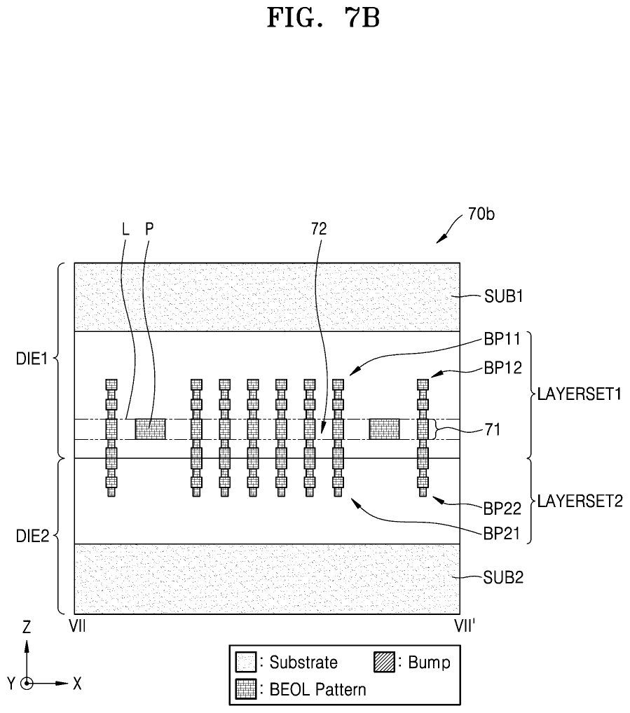

Referring to FIG. 5B, the inductor L may be disposed between the vertical interconnects. For example, as shown in FIG. 5B, the structure (e.g., pattern) of the inductor L may be offset from each of the vertical interconnects in at least one of the X-axis direction or the Y-axis direction and thus may not overlap any of the vertical interconnects in the Z-axis direction. The inductor L may include a pattern formed in the first layer LAYER1 and may include the first terminal T1 and the second terminal T2. As will be described later with reference to FIGS. 7A and 7B, the first layer LAYER1 in which the pattern of the inductor L is formed may be one of layers of the vertical interconnects. As will be described later with reference to FIGS. 7A and 7B, the first layer LAYER1 in which the pattern of the inductor L is formed may be thicker than each of the other layers of the vertical interconnects. The vertical interconnects may include vertical interconnects disposed in the inner region 52 of the inductor L (e.g., at least partially overlapping the inner region 52 in the Z-axis direction) and vertical interconnects disposed outside the inductor L (e.g., not overlapping any part of the pattern or inner region of the inductor L in the Z-axis direction). Therefore, a region in which the inductor L is disposed and a region in which the vertical interconnects are disposed may at least partially overlap each other (e.g., in the Z-axis direction), and an integrated circuit 50b may have a reduced area (e.g., may occupy a reduced area in the XY plane extending in the X-axis and Y-axis directions). Examples of cross-sections of the integrated circuit 50b of FIG. 5B cut along a plane including the X-axis and the Z-axis will be described later with reference to FIGS. 7A and 7B.

FIGS. 6A and 6B are cross-sectional views of examples of integrated circuits according to some example embodiments. For example, the cross-sectional views of FIGS. 6A and 6B show integrated circuits 60a and 60b including two dies stacked in the vertical direction, that is, the first die DIE1 and the second die DIE2. As shown, FIGS. 6A and 6B may be cross-sectional views of an integrated circuit taken along a line VI-VI′ in FIG. 5A. Hereinafter, descriptions of FIGS. 6A and 6B identical to those given above with reference to drawings (e.g., example embodiments shown in FIGS. 3A-4B) will be omitted.

Referring to FIG. 6A, an integrated circuit 60a may include the first die DIE1 and the second die DIE2, and the first die DIE1 may be stacked on the second die DIE2 (e.g., in the Z-axis direction). The first die DIE1 may include the first substrate SUB1, and the second die DIE2 may include the second substrate SUB2. The first substrate SUB1 may be adjacent to the second die DIE2, and the first die DIE1 may include TSVs penetrating through the first substrate SUB1 (e.g., penetrating in the Z-axis direction). BEOL patterns may be disposed over the first substrate SUB1 (e.g., at least partially overlapping the first substrate SUB1 in the Z-axis direction), and TSVs respectively connected to the BEOL patterns (e.g., TSVs connected to separate, respective BEOL patterns) may penetrate through the first substrate SUB1 in the Z-axis direction. For example, as shown in FIG. 6A, a first TSV TSV1 may penetrate through the first substrate SUB1 in the Z-axis direction and may be connected to a first BEOL pattern BP1 disposed on the first substrate SUB1. The second die DIE2 may include vertical interconnects electrically connected to the vertical interconnects of the first die DIE1, respectively. For example, the second die DIE2 may include a second BEOL pattern BP2 electrically connected to the first TSV TSV1 of the first die DIE1 and aligned with (e.g., at least partially overlapping) the first TSV TSV1 in the Z-axis direction.

The integrated circuit 60a may include a plurality of bumps BM1 between the first die DIE1 and the second die DIE2. For example, as shown in FIG. 6A, the bumps BM1 may be disposed between TSVs (e.g., separate, respective TSVs) of the first die DIE1 and BEOL patterns of the second die DIE2 in the Z-axis direction. Therefore, the TSVs of the first die DIE1 and the BEOL patterns of the second die DIE2 may be electrically connected to each other through the bumps.

As shown in FIG. 6A, the first and second dies DIE1 and DIE2 may include respective first and second sets of one or more layers LAYERSET1 and LAYERSET2 which may include portions of the respective dies DIE1 and DIE2 that exclude the respective first and second substrates SUB1 and SUB2 thereof. The first die DIE1 may be understood to include the first substrate SUB1 and the first set of one or more layers LAYERSET1. The second die DIE2 may be understood to include the second substrate SUB2 and the second set of one or more layers LAYERSET2. As shown, the first BEOL pattern BP1 may be located in, at least partially surrounded by, and/or at least partially penetrate one or more layers of the first set of one or more layers LAYERSET1. As shown, the second BEOL pattern BP2 may be located in, at least partially surrounded by, and/or at least partially penetrate one or more layers of the second set of one or more layers LAYERSET2. The respective first and second sets of one or more layers LAYERSET1 and LAYERSET2 may include one or more layers including one or more patterns of insulating material (e.g., silicon oxide material), conductive material (e.g., metal such as copper, doped polysilicon, etc.), wiring patterns, circuitry patterns, or the like.

According to some example embodiments, as described above with reference to FIG. 5A, in first die DIE1, the inductor L may be disposed over vertical interconnects (e.g., offset from vertical interconnects in the Z-axis direction and at least partially overlapping vertical interconnects in the Z-axis direction). The first set of one or more layers LAYERSET1 in the first die DIE1 may include at least one first layer LAYER1, and the at least one first layer LAYER1 may include a pattern of material P that at least partially defines the inductor L, such that the inductor L may be understood to be included in (e.g., at least partially defined by) a pattern of material P of the at least one first layer LAYER1. As shown in FIG. 6A, the inductor L may be disposed over (e.g., may at least partially overlap in the Z-axis direction) vertical interconnects including TSVs and BEOL patterns in first die DIE1. At least one vertical interconnect may at least partially overlap the pattern of the inductor L in the Z-axis direction, and at least one vertical interconnect may at least partially overlap the inner region 62 of the inductor L in the Z-axis direction. The inductor L may be spaced apart (e.g., offset) from the vertical interconnects in the Z-axis direction, and, according to some example embodiments, a layer in which the pattern of the inductor L is formed (e.g., the material P comprising and/or defining the pattern of the inductor L in the at least one first layer LAYER1) may be thicker (e.g., thicker in the Z-axis direction) than each of layers of the vertical interconnects.

Referring to FIG. 6B, an integrated circuit 60b may include the first die DIE1 and the second die DIE2, and the first die DIE1 may be stacked on the second die DIE2. The first die DIE1 may include the first substrate SUB1, and the second die DIE2 may include the second substrate SUB2. The first substrate SUB1 may be adjacent to the second die DIE2, and the first die DIE1 may include TSVs penetrating through the first substrate SUB1. BEOL patterns may be disposed over the first substrate SUB1, and TSVs respectively connected to the BEOL patterns may penetrate through the first substrate SUB1 in the Z-axis direction. For example, as shown in FIG. 6B, the first TSV TSV1 may penetrate through the first substrate SUB1 in the Z-axis direction and may be connected to the first BEOL pattern BP1 disposed over the first substrate SUB1. The second die DIE2 may include vertical interconnects electrically connected to the vertical interconnects of the first die DIE1, respectively. For example, the second die DIE2 may include the second BEOL pattern BP2 electrically connected to the first TSV TSV1 of the first die DIE1 and aligned with the first TSV TSV1 in the Z-axis direction. As shown in FIG. 6B, the first and second dies DIE1 and DIE2 may include respective first and second sets of one or more layers LAYERSET1 and LAYERSET2 which may include portions of the respective dies DIE1 and DIE2 that exclude the respective first and second substrates SUB1 and SUB2 thereof. In some example embodiments, the first BEOL pattern BP1 of the first die DIE1 may at least partially comprise a first circuit configured to process an analog signal, and the second BEOL pattern BP2 may at least partially comprise a second circuit configured to transmit a plurality of signals to the first circuit and/or receive a plurality of signals from the first circuit.

The first die DIE1 and the second die DIE2 may be interconnected (e.g., directly interconnected) through hybrid bonding. As described above with reference to FIG. 3B, the hybrid bonding may include interfacial bonding between oxide surfaces and interfacial bonding between metal surfaces and may be HCB when a metal constituting the metal surfaces is Cu. Due to the hybrid bonding, as shown in FIG. 6B, the BEOL patterns of the first die DIE1 and the BEOL patterns of the second die DIE2 may be bonded to each other at the interface between the first die DIE1 and the second die DIE2. Compared to the integrated circuit 60a of FIG. 6A, bumps may be omitted in the integrated circuit 60b of FIG. 6B.

According to some example embodiments, as described above with reference to FIG. 5A, in first die DIE1, the inductor L may be disposed over vertical interconnects (e.g., offset from vertical interconnects in the Z-axis direction and at least partially overlapping vertical interconnects in the Z-axis direction). The first set of one or more layers LAYERSET1 in the first die DIE1 may include at least one first layer LAYER1, and the at least one first layer LAYER1 may include a pattern of material P that at least partially defines the inductor L, such that the inductor L may be understood to be included in (e.g., at least partially defined by) a pattern of material P of the at least one first layer LAYER1. As shown in FIG. 6B, the inductor L may be disposed over vertical interconnects including TSVs and BEOL patterns in first die DIE1. At least one vertical interconnect may overlap the pattern of the inductor L in the Z-axis direction, and at least one vertical interconnect may overlap the inner region of the inductor L in the Z-axis direction. The inductor L may be spaced apart from the vertical interconnects in the Z-axis direction, and a layer in which the pattern of the inductor L is formed may be thicker than each of layers of the vertical interconnects.

FIGS. 7A and 7B are cross-sectional views of examples of integrated circuits according to some example embodiments. For example, the cross-sectional views of FIGS. 7A and 7B show integrated circuits 70a and 70b including two dies stacked in the vertical direction, that is, the first die DIE1 and the second die DIE2. As shown, FIGS. 7A and 7B may be cross-sectional views of an integrated circuit taken along a line VII-VII′ in FIG. 5B. Hereinafter, descriptions of FIGS. 7A and 7B identical to those given above with reference to drawings will be omitted.

Referring to FIG. 7A, an integrated circuit 70a may include the first die DIE1 and the second die DIE2, and the first die DIE1 may be stacked on the second die DIE2 (e.g., in the Z-axis direction). The first die DIE1 may include the first substrate SUB1, and the second die DIE2 may include the second substrate SUB2. As shown in FIG. 7A, the first and second dies DIE1 and DIE2 may include respective first and second sets of one or more layers LAYERSET1 and LAYERSET2 which may include portions of the respective dies DIE1 and DIE2 that exclude the respective first and second substrates SUB1 and SUB2 thereof. The first substrate SUB1 may be spaced apart from the second die DIE2, and BEOL patterns of the first die DIE1 may be disposed under the first substrate SUB1. The second die DIE2 may include vertical interconnects electrically connected to the vertical interconnects of the first die DIE1, respectively (e.g., the second die DIE2 may include vertical interconnects electrically connected to separate, respective vertical interconnects of the vertical interconnects of the first die DIE1). For example, the second die DIE2 may include BEOL patterns BP21 and BP22 electrically connected to BEOL patterns BP11 and BP12 of the first die DIE1 and aligned with the BEOL patterns BP11 and BP12 in the Z-axis direction, respectively.

The integrated circuit 70a may include a plurality of bumps BM1 between the first die DIE1 and the second die DIE2. For example, as shown in FIG. 7A, bumps BM1 may be disposed between the first die DIE1 and the second die DIE2. Therefore, a BEOL pattern BP12 of the first die DIE1 and a BEOL pattern BP22 of the second die DIE2 may be electrically connected to each other through a bump BM1.

According to some example embodiments, as described above with reference to FIG. 5B, in the first die DIE1 the inductor L may be disposed between the vertical interconnects, and the inductor L may include a pattern formed in at least one layer from among layers of the vertical interconnects (e.g., one or more layers LAYERSET1). For example, as shown in FIG. 7A, the inductor L may include a pattern (e.g., a pattern of material P) formed in a layer 71 from among layers of vertical interconnects, and the vertical interconnects (also referred to herein as first vertical interconnects, first conductive interconnects, etc.) may also include a pattern formed in (e.g., included in and/or at least partially defined by) the layer 71. The vertical interconnects may include vertical interconnects BP11 (also referred to herein as first vertical interconnects, first conductive interconnects, etc.) penetrating through the inner region 72 of the inductor L, for example overlapping the inner region 72 in the Z-axis direction and between opposing surfaces of the pattern of the inductor L that at least partially define the inner diameter D_IN in the X-axis and/or Y-axis direction (and thus at least partially inside the inductor L in the layer 71 and/or at least partially surrounded by the pattern of the inductor L in the layer 71 in the X-axis and/or Y-axis direction) and vertical interconnects BP12 (also referred to herein as additional vertical interconnects, additional first vertical interconnects, additional conductive interconnects, additional first conductive interconnects, etc.) disposed outside the inductor L (e.g., not overlapping the pattern of the inductor L or the inner region 72 of the inductor L in the Z-axis direction). According to some example embodiments, the layer 71 may be thicker (e.g., thicker in the Z-axis direction) than each of the other layers of the vertical interconnects.

Referring to FIG. 7B, an integrated circuit 70b may include the first die DIE1 and the second die DIE2, and the first die DIE1 may be stacked on the second die DIE2 (e.g., in the Z-axis direction). The first die DIE1 may include the first substrate SUB1, and the second die DIE2 may include the second substrate SUB2. The first substrate SUB1 may be spaced apart from the second die DIE2, and BEOL patterns of the first die DIE1 may be disposed under the first substrate SUB1 (e.g., in the Z-axis direction). The second die DIE2 may include vertical interconnects electrically connected to the vertical interconnects of the first die DIE1, respectively. For example, the second die DIE2 may include the BEOL patterns BP21 and BP22 electrically connected to the BEOL patterns BP11 and BP12 of the first die DIE1 and aligned with (e.g., at least partially overlapping) the BEOL patterns BP11 and BP12 in the Z-axis direction, respectively. As shown in FIG. 7B, the first and second dies DIE1 and DIE2 may include respective first and second sets of one or more layers LAYERSET1 and LAYERSET2 which may include portions of the respective dies DIE1 and DIE2 that exclude the respective first and second substrates SUB1 and SUB2 thereof.

The first die DIE1 and the second die DIE2 may be interconnected (e.g., directly interconnected) through hybrid bonding. As described above with reference to FIG. 3B, the hybrid bonding may include interfacial bonding between oxide surfaces and interfacial bonding between metal surfaces and may be HCB when a metal constituting the metal surfaces is Cu. Due to the hybrid bonding, the BEOL patterns of the first die DIE1 and the BEOL patterns of the second die DIE2 may be bonded to each other at the interface between the first die DIE1 and the second die DIE2. For example, as shown in FIG. 7B, the BEOL patterns BP11 and BP12 of the first die DIE1 and the BEOL patterns BP21 and BP22 of the second die DIE2 may be bonded to each other, respectively. Compared to the integrated circuit 70a of FIG. 7A, bumps may be omitted in the integrated circuit 70b of FIG. 7B.

According to some example embodiments, as described above with reference to FIG. 5B, in the first die DIE1 the inductor L may be disposed between the vertical interconnects, and the inductor L may include a pattern formed in at least one layer from among layers of the vertical interconnects (e.g., one or more layers LAYERSET1). For example, as shown in FIG. 7B, the inductor L may include a pattern (e.g., a pattern of material P) formed in a layer 71 from among layers of vertical interconnects, and the vertical interconnects may also include a pattern formed in (e.g., included in and/or at least partially defined by) the layer 71. The vertical interconnects may include vertical interconnects BP11 penetrating through the inner region 72 of the inductor L and vertical interconnects BP12 disposed outside the inductor L (e.g., not overlapping the pattern of the inductor L or the inner region 72 of the inductor L). According to some example embodiments, the layer 71 may be thicker (e.g., thicker in the Z-axis direction) than each of the other layers of the vertical interconnects.

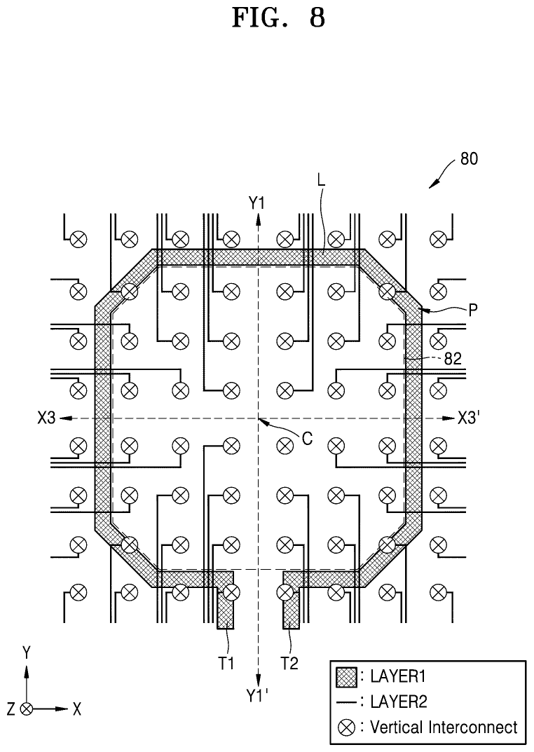

FIG. 8 is a plan view of an integrated circuit 80 according to some example embodiments. For example, FIG. 8 shows the integrated circuit 80 viewed in the −Z axis direction. As described above with reference to FIGS. 5A, 6A, and 6B, the integrated circuit 80 may include vertical interconnects and the inductor L, wherein the inductor L may be formed in a first layer LAYER1 over (e.g., in the Z-axis direction) the vertical interconnects. Although FIG. 8 shows some example embodiments in which the inductor L is disposed over (e.g., vertically offset from in the Z-axis direction) the vertical interconnects, descriptions given below with reference to FIG. 8 is also applicable to some example embodiments in which the inductor L is disposed between (e.g., at least partially overlapping in the X-axis and/or Y-axis directions) vertical interconnects as described above with reference to FIGS. 5B, 7A, and 7B.

According to some example embodiments, vertical interconnects may be routed based on the inductor L. For example, the integrated circuit 80 may include wires (or patterns) for routing vertical interconnects in a second layer LAYER2 below the first layer LAYER1, and the wires may be disposed based on the inductor L. According to some example embodiments, a differential signal may be applied to the first terminal T1 and the second terminal T2 of the inductor L. For example, the integrated circuit 80 may be configured to apply a differential signal to the first terminal T1 and the second terminal T2 of the inductor L and thus may be configured to apply the differential signal to the inductor L. To not to affect the differential signal, the vertical interconnects may be disposed symmetrically, and the wires routing the vertical interconnects, i.e. patterns of the second layer LAYER2, may also be disposed symmetrically. For example, as shown in FIG. 8, the first terminal T1 and the second terminal T2 may be spaced apart from each other in the X-axis direction, and the vertical interconnections and the wires may be symmetrically disposed around a line Y1-Y1′ parallel to the Y-axis and intersecting the center of the inductor L. Accordingly, the vertical interconnects and the wires (also referred to herein collectively as a plurality of conductive patterns) in a region that overlaps the inductor L (e.g., the pattern of material P and the inner region 82) may exhibit reflective symmetry around the line Y1-Y1′ such that the line Y1-Y1′ is an axis of symmetry (also referred to herein as an axis of reflective symmetry). According to some example embodiments, the vertical interconnects and the wires may be disposed symmetrically around a line X3-X3′ parallel to the X-axis and intersecting the center of the inductor L. Accordingly, the vertical interconnects and the wires (also referred to herein collectively as a plurality of conductive patterns) may exhibit reflective symmetry around the line X3-X3′ such that the line X3-X3′ is an axis of symmetry (also referred to herein as an axis of reflective symmetry). Therefore, the vertical interconnects and the conductive patterns of the second layer LAYER2 may provide a pattern shield to the inductor L. The X-axis direction and the Y-axis direction may each extend parallel to an in-plane direction of a substrate of the integrated circuit 80.

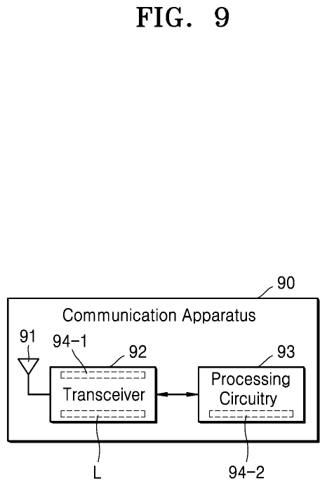

FIG. 9 is a block diagram showing a communication device 90 according to some example embodiments. According to some example embodiments, the communication device 90 may include an integrated circuit or a semiconductor package including the inductor and vertical interconnects described above with reference to the drawings. As shown in FIG. 9, the communication device 90 may include an antenna 91, a transceiver 92, and a processing circuitry 93.

The communication device 90 may communicate wirelessly with another communication device through the antenna 91. For example, the communication device 90 may be included in a wireless communication system, and the wireless communication system may be, but is not limited to, a wireless communication system using a cellular network such as a 5th generation wireless (5G) New Radio (NR) system, a Long Term Evolution (LTE) system, and an LTE-Advanced system, a Code Division Multiple Access (CDMA) system, and a Global System for Mobile Communications (GSM) system, a Wireless Personal Area Network (WPAN) system, or any other wireless communication system. When the wireless communication system uses a cellular network, the communication device 90 may be included in a base station and/or a terminal.

The transceiver 92 may process a signal received through the antenna 91, generate a signal to be transmitted, and output (e.g., transmit) a generated signal to the antenna 91. For example, the transceiver 92 may include a receiving circuit including a low noise amplifier (LNA), a filter, a mixer, etc., and a transmitting circuit including a power amplifier (PA), a filter, a mixer, etc. The receiving circuit and/or the transmitting circuit may process analog signals and may include active devices such as transistors as well as passive devices such as capacitors and inductors.

The processing circuitry 93 may process signals received from the transceiver 92 and may provide signals to the transceiver 92. For example, the processing circuitry 93 may include circuits for processing mixed signals, such as an analog-to-digital converter (ADC) or a digital-to-analog converter (DAC). Also, the processing circuitry 93 may include a logic circuit that processes digital signals.

The transceiver 92 and the processing circuitry 93 may be manufactured through a semiconductor process. When the transceiver 92 and the processing circuitry 93 are integrated into one die, due to analog circuits and logic circuits demanding different sub-processes of a semiconductor process, the die may have a large area, the cost of the semiconductor process may increase, and the yield of the die may decrease. Therefore, the transceiver 92 including an analog circuit and the processing circuitry 93 including a logic circuit may respectively be integrated into two dies independently of each other, and the two dies may be interconnected. To interconnect two dies, the two dies may each include vertical interconnects.

According to some example embodiments, the transceiver 92 may include an LC oscillator, and thus the transceiver 92 may include at least one inductor. In some example embodiments, the communication apparatus 90 may include an integrated circuit including at least one inductor, including an integrated circuit according to some example embodiments. The transceiver 92 may comprise a first circuit 94-1 and at least one inductor L in a first die DIE1 according to some example embodiments, where the first circuit 94-1 is configured to process an analog signal. The processing circuitry 93 may comprise or define a second circuit 94-2 in a second die DIE2 according to some example embodiments, where the second circuit 94-2 is configured to perform at least one of transmitting a plurality of signals to the first circuit 94-1 or receiving a plurality of signals from the first circuit 94-1. The first circuit 94-1 may be at least partially defined by one or more patterns, layers, or the like in the first substrate SUB1 and/or the first set of one or more layers LAYERSET1 of the first die DIE1 in some example embodiments, including example embodiments shown in FIGS. 3A-3B, 4A-4B, 6A-6B, and/or 7A-7B. The second circuit 94-2 may be at least partially defined by one or more patterns, layers, or the like in the second substrate SUB2 and/or the second set of one or more layers LAYERSET2 of the second die DIE2. As described above with reference to the drawings, the inductor may overlap the vertical interconnects in the vertical direction, and thus the die of transceiver 92 may have a reduced area. Also, spatial constraints on the inductor may be reduced, and thus the transceiver 92 may easily implement an inductor with dimensions that provide a desired inductance.

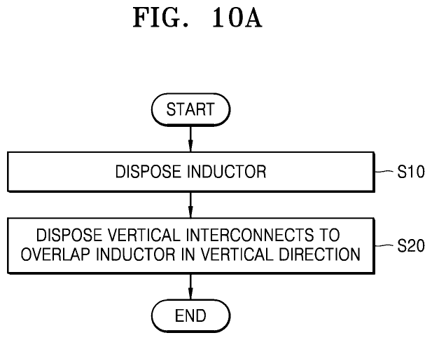

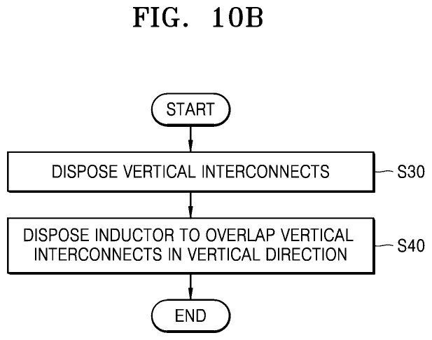

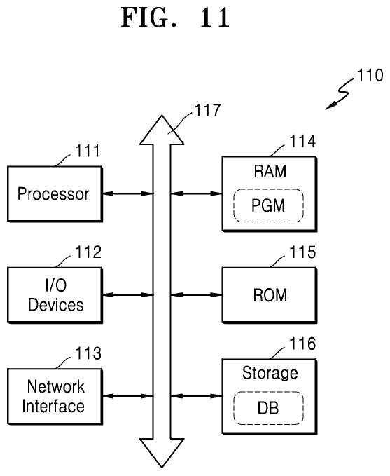

FIGS. 10A and 10B are flowcharts of examples of methods of designing an integrated circuit according to some example embodiments. For example, the flowcharts of FIGS. 10A and 10B illustrate methods of designing integrated circuits including inductors and vertical interconnects overlapping each other in a vertical direction, including an integrated circuit according to some example embodiments. According to some example embodiments, the method of FIGS. 10A and 10B may be performed by a semiconductor design tool, and the semiconductor design tool may be executed on a computing system, such as a computing system 110 of FIG. 11.

Referring to FIG. 10A, a method of designing an integrated circuit may include operations S10 and S20. In operation S10, an inductor may be disposed. For example, an inductor having an inductance demanded by an analog circuit included in an integrated circuit may be designed, and a designed inductor may be disposed. As described above with reference to the drawings, the inductor may include a pattern formed in at least one layer on a substrate, and the shape of the pattern may be defined based on the inductance.

In operation S20, vertical interconnects may be disposed to overlap the inductor in the vertical direction. As described above with reference to the drawings, the vertical interconnects may extend in the vertical direction to communicate with another die and may include patterns formed in a plurality of layers. For example, a vertical interconnect may include a metal pattern in a metal layer and a via and/or a TSV in a via layer. The die may include vertical interconnects, and a semiconductor design tool may reduce the area of an integrated circuit by arranging the vertical interconnects to overlap the inductor in the vertical direction. According to some example embodiments, as described above with reference to FIGS. 6A and 6B, the inductor may be disposed in an upper layer of a BEOL, the semiconductor design tool may dispose the vertical interconnects below the inductor, and the vertical interconnects may each include a TSV that penetrates through a substrate in the vertical direction. According to some example embodiments, as described above with reference to FIGS. 7A and 7B, the inductor may be disposed in at least one of layers of the vertical interconnects, and the semiconductor design tool may dispose the vertical interconnects to avoid the pattern of the inductor.

Referring to FIG. 10B, a method of designing an integrated circuit may include operations S30 and S40. In operation S30, vertical interconnects may be disposed. For example, a semiconductor design tool may dispose vertical interconnects in pre-defined region to communicate with another die. According to some example embodiments, the vertical interconnects may be disposed in an array-like shape as described above with reference to the drawings.

In operation S40, an inductor may be disposed to overlap the vertical interconnects in the vertical direction. For example, an inductor having an inductance demanded by an analog circuit included in an integrated circuit may be designed, and a designed inductor may be disposed. According to some example embodiments, as described above with reference to FIGS. 6A and 6B, the inductor may be disposed in an upper layer of a BEOL, the semiconductor design tool may dispose the vertical interconnects below the inductor, and the vertical interconnects may each include a TSV that penetrates through a substrate in the vertical direction.

FIG. 11 is a block diagram showing a computing system 110 including a memory storing a program, according to some example embodiments. At least some of operations included in a method of designing an integrated circuit according to some example embodiments (e.g., operations of the above-stated flowchart) may be performed by the computing system (or a computer) 110.

The computing system 110 may be a stationary computing system such as a desktop computer, a workstation, or a server or a portable computing system such as a laptop computer. As shown in FIG. 11, the computing system 110 may include a processor 111, input/output (I/O) devices 112, a network interface 113, a RAM 114, a ROM 115, and a storage 116. The processor 111, the input/output devices 112, the network interface 113, the RAM 114, the ROM 115, and the storage 116 may be connected to a bus 117 and may communicate with one another through the bus 117.

The processor 111 may be referred to as a processing unit and, for example, may include at least one core, e.g., a micro-processor, an application processor (AP), a digital signal processor (DSP), a graphics processing unit (GPU), etc., capable of executing an arbitrary instruction set (e.g., Intel Architecture-32 (IA-32), 64-bit extended IA-32, x86-64, PowerPC, Sparc, MIPS, ARM, IA-64, etc.). For example, the processor 111 may access a memory, that is, the RAM 114 or the ROM 115, through the bus 117 and may execute instructions stored in the RAM 114 or the ROM 115.

The RAM 114 may store a program PGM for a method of designing an integrated circuit according to some example embodiments or at least a portion of the program PGM, and the program PGM may instruct the processor 111 to perform at least some of operations included in the methods of designing an integrated circuit, e.g., the method of FIGS. 10A and 10B. In other words, the program PGM may include a plurality of instructions that may be executed by the processor 111, and the instructions included in the program PGM may instruct the processor 111 to perform at least some of operations included in the above-stated flowcharts, for example.

The storage 116 may not lose stored data even when power supplied to the computing system 110 is cut off. For example, the storage 116 may include a non-volatile memory device or a storage medium, such as magnetic tape, an optical disk, or a magnetic disk. Also, the storage 116 may be detachable from the computing system 110. The storage 116 may store the program PGM according to some example embodiments, and, before the program PGM is executed by the processor 111, the program PGM or at least a part thereof may be loaded to the RAM 114. Alternatively, the storage 116 may store a file written in a program language, and the program PGM generated from the file by a compiler or the like or at least a part of the program PGM may be loaded to the RAM 114. Also, as shown in FIG. 11, the storage 116 may store a database DB, and the database DB may include information needed for designing an integrated circuit.

The storage 116 may store data to be processed by the processor 111 or data processed by the processor 111. In other words, the processor 111 may generate data by processing data stored in the storage 116 according to the program PGM and may store generated data in the storage 116. For example, the storage 116 may include layout data that defines the layout of an integrated circuit. According to some example embodiments, layout data may have a format like GDSII and may include geometric information regarding cells and interconnections.

The input/output devices 112 may include an input device such as a keyboard and a pointing device and may include an output device such as a display device and a printer. For example, a user may trigger execution of the program PGM by the processor 111 through the input/output devices 112, input data necessary for designing an integrated circuit, and check a result of designing an integrated circuit, e.g., layout data.

The network interface 113 may provide access to a network outside the computing system 110. For example, a network may include a plurality of computing systems and communication links, and the communication links may include wired links, optical links, wireless links, or any other types of links. At least one of the processor 111, the I/O devices 112, the network interface 113, the RAM 114, the ROM 115, or the storage 116 may include an integrated circuit according to some example embodiments.

As described herein, any devices, systems, modules, portions, units, controllers, circuits, circuitry, and/or portions thereof according to any of the example embodiments, and/or any portions thereof may include, may be included in, and/or may be implemented by one or more processing devices such as hardware including logic circuits; a hardware/software combination such as a processor executing software; or a combination thereof. For example, the one or more processing devices more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the one or more processing devices may include a computer readable storage device (e.g., a memory) storing a program of instructions, for example a solid state drive (SSD), for example a non-transitory computer readable storage device, and the one or more processing devices may further include a processor (e.g., CPU) configured to execute the program of instructions to implement the functionality and/or methods performed by some or all of any devices, systems, modules, portions, units, controllers, circuits, circuitry, and/or portions thereof according to any of the example embodiments.

While the inventive concepts have been particularly shown and described with reference to some example embodiments thereof, it will be understood that various changes in form and details may be made therein without departing from the spirit and scope of the following claims.

What is claimed is:

1. An integrated circuit, comprising:
a first die, the first die including a first substrate and a plurality of through silicon vias (TSVs), the plurality of TSVs penetrating through the first substrate; and
a second die below the first die in a vertical direction, the second die including a second substrate and a plurality of conductive interconnects, the plurality of conductive interconnects electrically connected to separate, respective TSVs of the plurality of TSVs, the vertical direction extending perpendicular to an in-plane direction of the first die,
wherein the first die further includes an inductor in at least one first layer over the first substrate in the vertical direction, and
wherein the inductor at least partially overlaps at least one TSV of the plurality of TSVs in the vertical direction.

2. The integrated circuit of claim 1, further comprising a plurality of bumps between the first die and the second die, the plurality of bumps electrically connected to separate, respective TSVs of the plurality of TSVs.

3. The integrated circuit of claim 1, wherein the plurality of TSVs and the plurality of conductive interconnects are bonded to each other at an interface between the first die and the second die.

4. The integrated circuit of claim 1, wherein the first die further comprises a plurality of conductive patterns in a second layer, the plurality of conductive patterns electrically connected to separate, respective TSVs of the plurality of TSVs, the second layer between the first substrate and the at least one first layer.

5. The integrated circuit of claim 4, wherein the at least one first layer is thicker in the vertical direction than the second layer.

6. The integrated circuit of claim 4, wherein
the inductor includes a first terminal and a second terminal spaced apart from each other in a first horizontal direction, and the integrated circuit is configured to apply a differential signal to the first terminal and the second terminal, the first horizontal direction extending parallel to the in-plane direction of the first die, and
the plurality of conductive patterns exhibit reflective symmetry around an axis of symmetry in a region that overlaps the inductor in the vertical direction, the axis of symmetry parallel to a second horizontal direction, the second horizontal direction perpendicular to both the first horizontal direction and the vertical direction.

7. The integrated circuit of claim 1, wherein the first die comprises an analog circuit, the analog circuit including the inductor, the analog circuit configured to process at least one of
a signal to be transmitted through an antenna, or
a signal received through the antenna.

8. An integrated circuit, comprising:
a first die, the first die including a first substrate and a plurality of first conductive interconnects, the plurality of first conductive interconnects below the first substrate; and
a second die below the first die in a vertical direction, the second die including a plurality of second conductive interconnects, the plurality of second conductive interconnects electrically connected to separate, respective first conductive interconnects of the plurality of first conductive interconnects, the vertical direction extending perpendicular to an in-plane direction of the first die,
wherein the first die further includes an inductor in at least one first layer below the first substrate in the vertical direction, and
wherein the plurality of first conductive interconnects includes at least one first conductive interconnect, the at least one first conductive interconnect including a pattern at least partially inside the inductor in the at least one first layer.

9. The integrated circuit of claim 8, wherein the plurality of first conductive interconnects comprises at least one additional first conductive interconnect, the at least one additional first conductive interconnect comprising a pattern outside the inductor in the at least one first layer.

10. The integrated circuit of claim 8, further comprising a plurality of bumps between the first die and the second die, the plurality of bumps electrically connected to separate, respective first conductive interconnects of the plurality of first conductive interconnects.

11. The integrated circuit of claim 8, wherein the plurality of first conductive interconnects and the plurality of second conductive interconnects are bonded to each other at an interface between the first die and the second die.

12. The integrated circuit of claim 8, wherein each separate first conductive interconnect of the plurality of first conductive interconnects includes a plurality of conductive patterns in a second layer, the second layer between the first substrate and the at least one first layer.

13. The integrated circuit of claim 12, wherein the at least one first layer is thicker than the second layer.

14. The integrated circuit of claim 12, wherein
the inductor includes a first terminal and a second terminal spaced apart from each other in a first horizontal direction, and the integrated circuit is configured to apply a differential signal to the first terminal and the second terminal, the first horizontal direction extending parallel to the in-plane direction of the first die, and
the plurality of conductive patterns exhibit reflective symmetry around an axis of symmetry in a region that overlaps the inductor in the vertical direction, the axis of symmetry parallel to a second horizontal direction, the second horizontal direction perpendicular to both the first horizontal direction and the vertical direction.

15. The integrated circuit of claim 8, wherein the first die comprises an analog circuit, the analog circuit including the inductor, the analog circuit configured to process at least one of
a signal to be transmitted through an antenna, and
a signal received through the antenna.

16. An integrated circuit, comprising:
a first die, the first die including
an inductor in at least one first layer, and
a first circuit configured to process an analog signal; and
a second die below the first die, the second die including a second circuit, the second circuit configured to perform at least one of
transmitting a plurality of signals to the first circuit, or
receiving a plurality of signals from the first circuit,
wherein the first die further includes a plurality of first conductive interconnects, the integrated circuit configured to apply the plurality of signals to the plurality of first conductive interconnects, and
wherein at least one first conductive interconnect of the plurality of first conductive interconnects at least partially overlaps an inner region of the inductor in a vertical direction, the vertical direction extending perpendicular to an in-plane direction of the first die.

17. The integrated circuit of claim 16, wherein
the first die comprises a first substrate,
the plurality of first conductive interconnects each comprise a separate plurality of through silicon vias (TSVs) penetrating through the first substrate, and
the inductor is over the plurality of first conductive interconnects.

18. The integrated circuit of claim 16, wherein the plurality of first conductive interconnects comprise at least one first conductive interconnect, the at least one first conductive interconnect comprising a pattern inside the inductor in the at least one first layer.

19. The integrated circuit of claim 16, further comprising a plurality of bumps between the first die and the second die, the plurality of bumps electrically connected to separate, respective first conductive interconnects of the plurality of first conductive interconnects.

20. The integrated circuit of claim 16, wherein
the second die further comprises a second substrate and a plurality of second conductive interconnects, the integrated circuit configured to apply the plurality of signals to the plurality of second conductive interconnects, and
the plurality of first conductive interconnects and the plurality of second conductive interconnects are bonded to each other at an interface between the first die and the second die.
